(19) United States
(12) Patent Application Publication
(10) Pub. No.: US 2013/0087605 A1
(43) Pub. Date: Apr. 11, 2013

(54) CONDUCTIVE BONDING MATERIAL, CONDUCTOR BONDING METHOD, AND SEMICONDUCTOR DEVICE PRODUCTION METHOD

(71) Applicants: Takashi KUBOTA, Chikuma (JP); Masayuki KITAJIMA, Yokohama (JP); Takatoyo YAMAKAMI, Nagano (JP); Kuniko ISHIKAWA, Nagano (JP)

(72) Inventors: Takashi KUBOTA, Chikuma (JP); Masayuki KITAJIMA, Yokohama (JP); Takatoyo YAMAKAMI, Nagano (JP); Kuniko ISHIKAWA, Nagano (JP)

(73) Assignee: FUJITSU LIMITED, Kawasaki-shi (JP)

(21) Appl. No.: 13/596,511

(22) Filed: Aug. 28, 2012

(30) Foreign Application Priority Data
Oct. 6, 2011 (JP) 2011-221817

(51) Int. Cl. B23K 35/24; B23K 31/02

(52) U.S. Cl. 228/256; 75/255; 148/24

(57) ABSTRACT

A conductive bonding material comprising: a first metal particle; a second metal particle having an average particle diameter larger than an average particle diameter of the first metal particle; and a third metal particle having an average particle diameter larger than the average particle diameter of the first metal particle, a relative density larger than a relative density of the first metal particle, and a melting point higher than a melting point of the second metal particle.

### CROSS-REFERENCE TO RELATED APPLICATION(S)

This application is based upon and claims the benefit of priority of the prior Japanese Patent Application No. 2011-221817, filed on Oct. 6, 2011, the entire contents of which are incorporated herein by reference.

### FIELD

The embodiments discussed herein are related to a conductive bonding material, a method for bonding a conductor by using the conductive bonding material, and a method for producing a semiconductor device.

### BACKGROUND

Various conductive bonding materials have been proposed as bonding materials used in bonding electronic parts such as semiconductor elements to wiring substrates such as glass epoxy substrates. Examples of the conductive bonding materials include metal pastes such as solder pastes. One of the desirable properties of the conductive bonding materials is that the solder after being bonded at a relatively low temperature of about 150° C. does not re-melt in the subsequent heat treatment. An example of the conductive bonding materials that have such a property is a variable melting point metal paste.

When this variable melting point metal paste is heated to a particular temperature or higher temperature, the melting point changes to a higher temperature.

[Patent document] Japanese Laid-open Patent Publication No. 2002-254194

Typically, a variable melting point metal paste contains Cu particles, which are particles of a metal having a high melting point. The Cu particles remain unmelted in the variable melting point metal paste even when the variable melting point metal paste is melted under heating. Accordingly, the surface of the variable melting point metal paste tends to exhibit irregularities, resulting in a decrease in gloss. When the solder bonded portion is subjected to an automatic appearance inspection using a laser beam or the like, diffused reflection of light occurs due to this phenomenon, which renders the automatic appearance inspection difficult to perform.

### SUMMARY

According to an aspect of the invention, A conductive bonding material includes a first metal particle; a second metal particle having an average particle diameter larger than an average particle diameter of the first metal particle; and a third metal particle having an average particle diameter larger than the average particle diameter of the first metal particle, a relative density larger than a relative density of the first metal particle, and a melting point higher than a melting point of the second metal particle.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a diagram illustrating a state in which irregularities are formed in a surface of a soldered portion by heat-treating a typical conductive bonding material and in which the conductive bonding material is supplied between a wiring substrate and an electronic part.

FIG. 1B is a diagram illustrating the state in which irregularities are formed in a surface of a soldered portion by heat-treating a typical conductive bonding material and in which the conductive bonding material is melted by heat.

FIG. 1C is a diagram illustrating the state in which irregularities are formed in a surface of a soldered portion by heat-treating a typical conductive bonding material and in which a Cu—Sn intermetallic compound is formed.

FIG. 1D is a diagram illustrating the state in which irregularities are formed in a surface of a soldered portion by heat-treating a typical conductive bonding material and in which the irregularities are formed by Cu particles that remained unmelted.

FIG. 2A is a photograph of a surface of a soldered portion before heating in performing bonding using a typical conductive bonding material.

FIG. 2B is a photograph of a surface of a soldered portion after heating in performing bonding using a typical conductive bonding material.

FIG. 3A is a diagram illustrating the state before heating in bonding a wiring substrate and an electronic part to each other by using a conductive bonding material according to an embodiment.

FIG. 3B is a diagram illustrating the state after heating in bonding a wiring substrate and an electronic part to each other by using a conductive bonding material according to an embodiment.

FIG. 4A is a diagram illustrating the state before heating in bonding a wiring substrate and an electronic part to each other by using a conductive bonding material according to an embodiment.

FIG. 4B is a diagram illustrating the state after heating in bonding a wiring substrate and an electronic part to each other by using a conductive bonding material according to an embodiment.

FIG. 5A is a schematic diagram illustrating an example of a step for producing a semiconductor device according to an embodiment.

FIG. 5B is a schematic diagram illustrating an example of a step for producing a semiconductor device according to an embodiment.

FIG. 5C is a schematic diagram illustrating an example of a step for producing a semiconductor device according to an embodiment.

FIG. 5D is a schematic diagram illustrating an example of a step for producing a semiconductor device according to an embodiment.

FIG. 5E is a schematic diagram illustrating an example of a step for producing a semiconductor device according to an embodiment.

FIG. 5F is a schematic diagram illustrating an example of a step for producing a semiconductor device according to an embodiment.

FIG. 5G is a schematic diagram illustrating an example of a step for producing a semiconductor device according to an embodiment.

FIG. 6 is a diagram illustrating an example of an electronic part. FIG. 7A is a schematic diagram of a mapping image photograph of Cu, Bi, and Sn measured with an energy dispersive X-ray microanalyzer after a wiring substrate and an electronic part were bonded to each other by using a conductive bonding material of Example 4.

FIG. 7B is a schematic diagram of a mapping image photograph of Cu measured with an energy dispersive X-ray microanalyzer after a wiring substrate and an electronic part were bonded to each other by using a conductive bonding material of Example 4.

FIG. 7C is a schematic diagram of a mapping image photograph of Bi measured with an energy dispersive X-ray microanalyzer after a wiring substrate and an electronic part were bonded to each other by using a conductive bonding material of Example 4.

FIG. 7D is a schematic diagram of a mapping image photograph of Sn measured with an energy dispersive X-ray microanalyzer after a wiring substrate and an electronic part were bonded to each other by using a conductive bonding material of Example 4.

FIG. 8 is a diagram illustrating the amount of aluminum particles added and surface states after heat melting in Example 22.

FIGS. 9A to 9D present Tables 1-1 to 1-4 indicating compositions of conductive bonding materials of Examples, Reference Example, and Comparative Examples and results of evaluating appearance and bonding strength.

FIG. 10 presents Table 2 indicating results of evaluating appearance and bonding strength.

### DESCRIPTION OF EMBODIMENTS

(Conductive Bonding Material)

The conductive bonding material according to an embodiment includes a first metal particle, a second metal particle, a third metal particle, a flux component, and, optionally, other desirable components.

<First Metal Particle>

The shape, structure, material, etc., of the first metal particle may be any and may be properly selected according to the purpose.

Examples of the shape of the first metal particle include globular, spherical, and rugby ball shapes. The structure of the first metal particle may be a single layer structure or a multilayer structure.

Examples of the first metal particle include particles composed of elemental metals, particle composed of alloys, and particle composed of metal compounds. Examples of the elemental metals include aluminum (relative density: 2.7) and gallium (relative density: 5.9).

Examples of the alloys include Sn—Al alloys, Sn—In alloys, and Sn-Bi alloys. These may be used alone or in combination. An example of the Sn-Al alloy is a Sn-55 Al alloy that contains Sn as a main component and Al in an amount of about 55 mass %. An example of the Sn—In alloy is a Sn-5 In alloy that contains Sn as a main component and In in an amount of about 5 mass %. An example of the Sn—Bi alloy is a Sn-5 Bi alloy that contains Sn as a main component and Bi in an amount of about 5 mass %.

Examples of the metal compounds include SnCl₂, SnBr, AgCl, AgBr, AgI, AgNO₃, and AlCl₃. These may be used alone or in combination. The metal compound has an activating effect during bonding (soldering) and a metal component (Ag) precipitates as a result of removal of an oxide coating film of a conductive bonding material as represented by the reaction formula below:

Sn+2AgCl→SnCl₂+2Ag (precipitation)

The average particle diameter of the first metal particle is smaller than that of the second and third metal particles, and is preferably 1 μm or less and more preferably 0.01 μm to 0.5 l μm. When the average diameter of the first metal particle is larger than that of the second and third metal particles, the first metal particle does not float in the surface of the soldered portion during the heat melting and irregularities occur in the surface of the conductive bonding material after the heat melting, thereby possibly failing to form metal coating films with satisfactory gloss. The average particle diameter may be measured with a particle size distribution analyzer employing a laser diffraction scattering technique.

The relative density of the first metal particle is smaller than the relative density of the third metal particle and is preferably 2.0 or more and 6.0 or less. When the relative density of the first metal particle is larger than the relative density of the third metal particle, the first metal particle does not float in the surface of the soldered portion during heat melting and irregularities occur in the surface of the conductive bonding material after the heat melting, thereby possibly failing to form metal coating films with satisfactory gloss. When the relative density exceeds 6.0, it may become difficult to use an automatic appearance inspection machine. The relative density may be measured by a dimension method or an Archimedean method, for example.

The melting point of the first metal particle is preferably lower than the melting point of the third metal particle and is more preferably 29° C. to 700° C. and yet more preferably 100° C. to 670° C. When the melting point of the first metal particle is higher than the melting point of the third metal particle, it becomes difficult to heat melt the first metal particle during the heat melting, the first metal particle does not float in the surface of the soldered portion, and irregularities occur in the surface of the conductive bonding material after the heat melting, thereby possibly failing to form metal coating films with satisfactory gloss. The melting point may be measured by differential scanning calorimetry (DSC), for example.

The first metal particle content relative to all metal components in the conductive bonding material is preferably 1.5 to 20 mass % and more preferably 2.5 to 15 mass %. When the first metal particle content is less than 1.5 mass %, irregularities occur in the surface of the conductive bonding material after heat melting and metal coating films with satisfactory gloss is not formed. At a first metal particle content exceeding 20 mass %, the amount of the first metal particle is undesirably high and the bonding strength may decrease. The first metal particle may be any particle and may be produced or purchased. An example of a method for producing the first metal particle is powderization through an atomizing method.

<Second Metal Particle>

The shape, structure, material, etc., of the second metal particle may be any and may be properly selected according to the purpose as long as the average particle diameter is larger than that of the first metal particle. Examples of the shape of the second metal particle include globular, spherical, and rugby ball shapes. The structure of the second metal particle may be a single layer structure or a multilayer structure.

Examples of the second metal particle include tin (Sn) particles, tin (Sn)-bismuth (Bi) alloy particles, tin (Sn)-bismuth (Bi)-silver (Ag) alloy particles, and tin (Sn)-indium (In) alloy particles. These may be used alone or in combination. An example of the Sn-Bi alloy is a Sn-58 Bi alloy containing Sn as a main component and Bi in an amount of about 58 mass %. An example of the Sn—Bi—Ag alloy is a Sn-57 Bi-1 Ag alloy containing Sn as a main component, Bi in an amount of about 57 mass %, and Ag in an amount of about 1 mass %. An example of the Sn—In alloy is a Sn-50 In alloy containing Sn as a main component and In in an amount of about 50 mass %.

The average diameter of the second metal particle is larger than that of the first metal particle and is about the same as that of the third metal particle, and is preferably 10 μm or more, more preferably 10 μm to 100 μm, and yet more preferably 10 μm to 40 μm. When the average particle diameter is less than 10 μm, the surface oxidation becomes significant and the solderability and wettability to solder are degraded. In contrast, when the average particle diameter exceeds 100 μm, the printability and diffusing property may be degraded. The average particle diameter may be measured with a particle size distribution analyzer employing a laser diffraction scattering technique.

The relative density of the second metal particle is preferably 3.5 to 11.0 and more preferably 4.0 to 7.0. The relative density may be measured by a dimension method or an Archimedean method, for example.

The melting point of the second metal particle is preferably 300° C. or lower and more preferably 100° C. to 250° C. When the melting point is higher than 300° C., remelting of solder during a heat treatment at about 240° C. performed in the subsequent step becomes difficult to suppress and the quality of bonding may become difficult to ensure. The melting point may be measured by DSC, for example.

The second metal particle content is preferably 50 to 90 mass % and more preferably 55 to 65 mass % relative to all metal components. The second metal particle may be any and may be produced or purchased. An example of a method for producing the second metal particle is powderization through an atomizing method.

<Third Metal Particle>

The shape, structure, material, etc., of the third metal particle may be any and may be properly selected according to the purpose as long as the average particle diameter is larger than that of the first metal particle, the relative density is larger than the first metal particle, and the melting point is higher than that of the second metal particle. Examples of the shape of the third metal particle include globular, spherical, and rugby ball shapes. The structure of the third metal particle may be a single layer structure or a multilayer structure.

Examples of the third metal particle include gold (Au) particles, silver (Ag) particles, copper (Cu) particles, gold (Au)-plated copper (Cu) particles, tin (Sn)-bismuth (Bi) alloy-plated copper (Cu) particles, and silver (Ag)-plated copper (Cu) particles. These may be used alone or in combination. An example of the Sn—Bi alloy-plated Cu particles include Sn-58 Bi-plated Cu particles. The plating method used in forming the Au-plated Cu particles, Sn—Bi alloy-plated Cu particles, and Ag-plated Cu particles may be any and may be property selected according to the purpose. An example of the plating method is electroless plating.

The average diameter of the third metal particle is larger than that of the first metal particle and is about the same as that of the second metal particle, and is preferably 10 μm or more, more preferably 10 μm to 100 μm, and yet more preferably 10 μm to 40 μm. When the average particle diameter is less than 10 μm, the surface oxidation becomes significant and the solderability and wettability to solder are degraded. In contrast, when the average particle diameter exceeds 100 μm, the printability and diffusing property may be degraded. The average particle diameter may be measured with a particle size distribution analyzer employing a laser diffraction scattering technique, for example.

The relative density of the third metal particle is larger than the relative density of the first metal particle and is preferably 8.0 or more and more preferably 8.9 to 19.3. When the relative density is less than 8.0, the difference in relative density between the first and third metal particles is reduced, irregularities occur in the surface of the conductive bonding material after heat melting, and a metal coating film with satisfactory gloss is not formed. The relative density may be measured by a dimension method or an Archimedean method, for example.

The melting point of the third metal particle is higher that the melting point of the second metal particle and is preferably 900° C. or more and more preferably 900° C. to 1100° C. When the melting point is less than 900° C., the third metal particle forms a low-melting-point alloy with the second metal particle and may cause remelting. The melting point may be measured by DSC, for example.

The third metal particle content relative to all metal components is preferably 10 to 50 mass % and more preferably 10 to 30 mass %. The third metal particle may be any and may be produced or purchased. An example of a method for producing the third metal particle is powderization through an atomizing method.

<Flux Component>

The flux component may be any and may be properly selected according to the purpose. The flux component is preferably an epoxy-based flux material, a rosin-based flux material, or a mixture thereof. Among these, an epoxy-based flux material is particularly preferably used to improve the bonding strength resulting from curing of the epoxy resin.

Epoxy-Based Flux Material

The epoxy-based flux material contains an epoxy resin, a carboxylic acid, and a solvent, and other optional components.

The epoxy resin may be any and may be properly selected according to the purpose. Examples thereof include thermosetting epoxy resins such as a bisphenol A epoxy resin, a bisphenol F epoxy resin, a novolac epoxy resin, and their modified forms. These may be used alone or in combination.

The carboxylic acid may be any and may be properly selected according to the purpose. Examples thereof include saturated aliphatic dicarboxylic acids, unsaturated aliphatic dicarboxylic acids, cyclic aliphatic dicarboxylic acids, amino-group-containing carboxylic acids, hydroxyl-group-containing carboxylic acids, heterocyclic dicarboxylic acids, and mixtures thereof. In particular, among these, succinic acid, glutaric acid, adipic acid, azelaic acid, dodecanedioic acid, itaconic acid, mesaconic acid, cyclobutanedicarboxylic acid, L-glutamic acid, citric acid, malic acid, thiopropionic acid, thiodibutyric acid, and dithioglycolic acid are preferable. Examples of the solvent include alcohols such as methanol, ethanol, and propanol, ethylene glycol-based solvents, diethylene glycol monohexyl ether, and octanediol. Additives such as a thixotropic agent, a chelating agent, a surfactant, and an antioxidant may be contained as the optional components. The epoxy-based flux material may be any and may be synthesized or purchased.

Rosin-Based Flux Material

The rosin-based flux material contains a rosin resin, an activator, a solvent, and other optional components.

Examples of the rosin resin include those mainly composed of natural rosin resins or modified rosin resins. Examples of the modified rosin resins include polymerized rosin, hydrogenated rosin, phenol resin-modified rosin, and maleic acid-modified rosin. Examples of the activator include inorganic activators and organic activators, e.g., halogen-based activators such as amine hydrochloride and organic acid-based activators. Examples of the solvent include ethylene glycol-based solvents, diethylene glycol monohexyl ether, and octanediol. Additives such as a thixotropic agent, a chelating agent, a surfactant, and an antioxidant may be contained as the optional components. The rosin-based flux material may be any and may be synthesized or purchased.

The flux component content in the conductive bonding material is preferably 5 to 50 mass % and more preferably 10 to 30 mass %.

<Other Optional Components>

The conductive bonding material may contain other optional components in addition to the metal component and the flux component described above. Examples of the optional components include a dispersing agent and an antioxidant.

The conductive bonding material of this embodiment is prepared by mixing a metal component including the first, second, and third metal particles, the flux components, and the optional components. The method and conditions of mixing may be any and may be properly selected according to the purpose by using a known mixing machine or stirring machine. Mixing is preferably conducted uniformly in a non-oxidizing atmosphere.

A conductive bonding material of related art has low cohesiveness during heat melting and has irregularities in the surface. Since the surface of the conductive bonding material after the heat treatment has low gloss, it has been difficult to determine with an automatic appearance inspection system whether bonding is achieved or not (presence or absence of heating history).

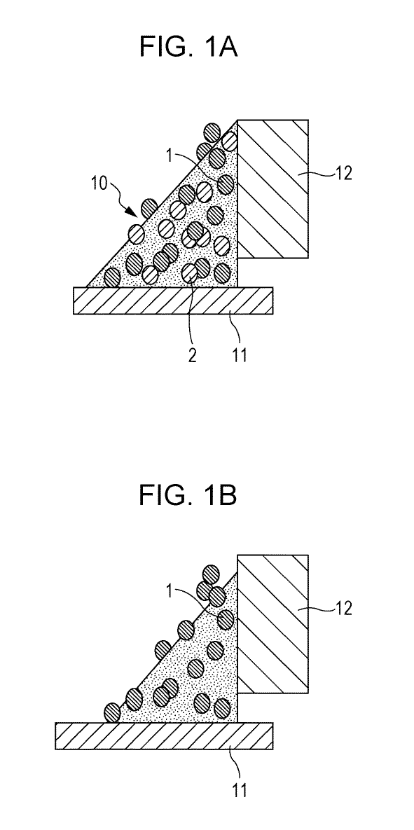

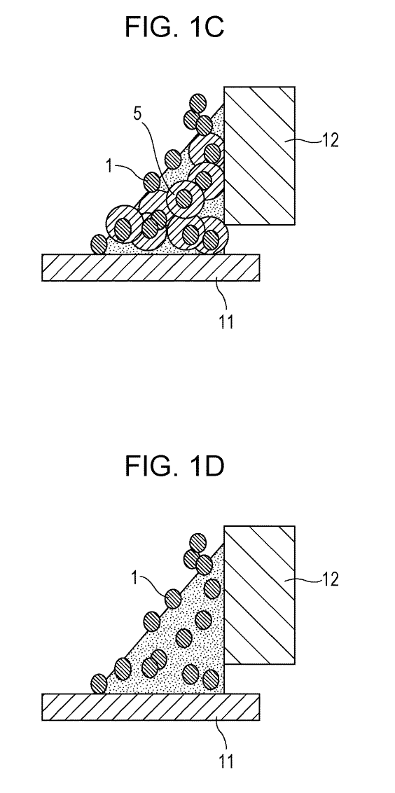

The mechanism with which irregularities are formed in the surface of a soldered portion as a result of heat-treating a typical conductive bonding material is described with reference to FIGS. 1A to 1D. FIG. 1A is a diagram illustrating a state in which a conductive bonding material is supplied between a wiring substrate and an electronic part. FIG. 1B is a diagram illustrating a conductive bonding material in a heat-melted state. FIG. 1C is a diagram illustrating formation of an Cu—Sn intermetallic compound. FIG. 1D illustrates irregularities occurring in the surface due to Cu particles that remain unmelted.

As illustrated in FIGS. 1A to 1D, Cu particles, which are high-melting-point metal particles 1 in a conductive bonding material 10, form a Cu—Sn-based intermetallic compound 5 (high melting point) during heat-melting in the process of bonding an electronic part 12 to a wiring substrate 11. However, due to wettability to solder and a cohesive effect induced by liquefying of solder particles, i.e., low-melting-point metal particles 2, the high-melting-point metal particles 1 that remain unmelted tend to float in the surface of the soldered portion. Due to the unmelted high-melting-point metal particles 1 remaining in the surface of the soldered portion, significant irregularities occur and gloss is reduced.

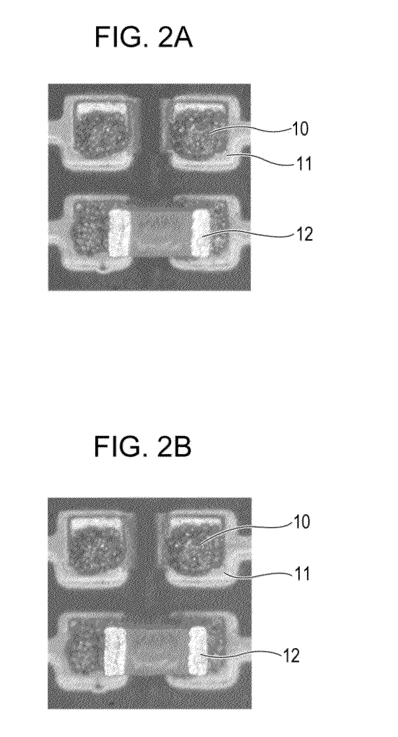

This may be confirmed also from FIGS. 2A and 2B. FIG. 2A is a photograph of a surface of a soldered portion before heating. FIG. 2B is a photograph of a surface of a soldered portion after heating. The conductive bonding material 10 of the related art has irregularities in the surface and low gloss and does not exhibit a significant change between before and after heating. Accordingly, when the soldered portion is subjected to automatic appearance inspection by using light (laser beam etc.), diffused reflection of light occurs, thereby making it difficult to conduct automatic appearance inspection. In FIGS. 2A and 2B, the component indicated by 11 is a wiring substrate and the component indicated by 12 is an electronic part.

If the heat treatment is not properly conducted during soldering using a variable melting point metal paste, the electrical connection between the electronic part and the wiring substrate and the mechanical strength are not reliably achieved and thus production becomes difficult. Soldering is usually conducted by using a heating device called a reflow furnace. However, the temperature inside the reflow furnace is instable and defects occur in soldered portions due to insufficient heating. Accordingly, an automatic appearance inspection system is used to inspect the presence and absence of gloss in the surface of the conductive bonding material after being passed through the reflow furnace, to pick products in which heating was insufficient, and to mark portions where the heating was insufficient.

Recent surface mount devices tend to use many ultra small size parts such as 0402 size chip devices (L: 0.4 mm×W: 0.2 mm×D: 0.2 mm). Accordingly, visual appearance inspection through human eye using microscopes does not meet the industrial standard in terms of quality (oversight of defects), time, and cost and inspection using automatic appearance inspection systems is desirable.

The conductive bonding material of this embodiment forms a metal coating film with satisfactory gloss since the first metal particle having a small diameter and a low relative density floats in the surface of the soldered portion during the heat melting and generates less irregularities in the surface of the conductive bonding material after the heat melting. As a result, diffused reflection of light during the automatic appearance inspection of the soldered portion between the wiring substrate and the electronic part is suppressed and the automatic appearance inspection system may be easily employed. Thus, the conductive bonding material may be used in various fields that use conductive bonding materials. The conductive bonding material is particularly suitable for use in a conductor bonding method and a semiconductor production method of embodiments described below.

(Conductor Bonding Method)

A conductor bonding method according to an embodiment includes a step of supplying a conductive bonding material, a step of bonding, and, optionally, other steps.

<Step of Supplying a Conductive Bonding Material>

The step of supplying a conductive bonding material is a step of supplying the conductive bonding material of an embodiment to an electrode of a wiring substrate, a terminal of an electronic part, or both.

<<Wiring Substrate>>

The shape, structure, size, etc., of the wiring substrate may be any and may be properly selected according to the purpose. An example of the shape is a plate shape. The structure may be a single layer structure or a multilayer structure. The size may be selected according to the size of the electrode or the like.

Examples of a substrate used in the wiring substrate include a glass substrate, a quartz substrate, a silicon substrate, a SiO₂ film-coated silicon substrate; and polymer substrates such as an epoxy resin substrate, a phenol resin substrate, a polyethylene terephthalate substrate, a polycarbonate substrate, a polystyrene substrate, and a polymethyl methacrylate substrate. These may be used alone or in combination. The substrate is preferably selected from a glass substrate, a quartz substrate, a silicon substrate, and a SiO₂-film-coated silicon substrate among these substrates. In particular, a silicon substrate and a SiO₂-film-coated silicon substrate are preferable.

The substrate may be produced or purchased. The thickness of the substrate may be any and may be properly selected according to the purpose. The thickness is preferably 100 μm or more and more preferably 500 μm or more. The size of the wiring substrate may be any and may be selected according to the purpose. For example, the substrate may be 10 mm to 200 mm in length, 10 mm to 200 mm in width, and 0.5 mm to 5 mm in thickness.

A wiring circuit board in which a wiring pattern is formed is used as the wiring substrate. The circuit board may be a single layer circuit board (single layer printed circuit board) or a multilayer circuit board (multilayer printed circuit board).

Examples of the metal constituting the electrode of the circuit board include Cu, Ag, Au, Ni, Sn, Al, Ti, Pd, and Si. Among these, Cu, Ag, and Au are particularly preferable. These metals may be formed as a surface portion of an electrode metal on the wiring substrate by any of various processes such as plating and bonding. When a conductive bonding material is applied to an electrode metal on a wiring substrate, the electrode metal on the substrate is usually subjected to a surface coating treatment to improve a connection between the conductive bonding material and the electrode metal on the wiring substrate. For example, when a copper electrode is used, a thin film of Sn, Au, Ni, or the like formed by plating is formed on the electrode. In particular, the above-described metals other than Au are preferably surface-treated with a flux or the like or subjected to pre-flux coating prior to application of the solder paste and then various metal plating, solder coating, etc., are preferably conducted since these metals have surfaces that are readily oxidizable.

<<Electronic Parts>>

The electronic part may be any electronic part that has a terminal and may be properly selected according to the purpose. Examples of the electronic part include chip components and semiconductor components.

The chip component may be any and may be properly selected according to the purpose. Examples thereof include capacitors and resistors.

The semiconductor component may be any and may be properly selected according to the purpose. Examples thereof include an integrated circuit, a large scale integration circuit, a transistor, a thyristor, and a diode.

The size of the electronic part may be any and may be properly selected according to the purpose. Examples thereof include 1608-type (1.6 mm×0.8 mm×0.8 mm) parts, 1005-type (1 mm×0.5 mm×0.5 mm) parts, 0603-type (0.6 mm×0.3 mm×0.3 mm) parts, and 0402-type (0.4 mm×0.2 mm×0.2 mm) parts.

<<Terminal>>

The terminal may be any and may be properly selected according to the purpose. Examples thereof include wires, metal wires, and printed wires formed of conductive pastes.

The material of the terminal may be any and may be properly selected according to the purpose. Examples thereof include metals such as Cu, Ni, Au, Al, Mo, and Cr, metal oxides such as ITO and IZO, and laminates or composites including these metals and/or metal oxides.

Supplying Method

The method for supplying the conductive bonding material may be any method as long as the conductive bonding material may be applied to a particular thickness or a particular coating amount and may be properly selected according to the purpose. Examples of the method include screen printing, transfer printing, dispenser discharging, and an ink jet method.

In the screen printing, a printer that uses a mask plate may be used. A typical printer includes a mechanism for fixing a wiring substrate or an electronic part, a mechanism for aligning a metal mask and an electrode of the substrate or a terminal of the electronic part, and a printing mechanism for allowing the mask plate to come into press-contact with the wiring substrate or electronic part and applying the conductive bonding material from above the mask through an opening in the mask onto the electrode of the wiring substrate or the terminal of the electronic part under the mask by using a squeegee for application. The mask plate may be made of various materials such as mesh-type or metal-type mask plates. Metal-type masks are widely used since they are compatible with a wide variety of particle sizes and are easy to clean during the process.

The transfer printing is a method of distributing a particular amount of conductive bonding material to the electrode of the wiring substrate or the terminal of the electronic part and includes forming a solid coating film of the conductive bonding material at a particular thickness by using a squeegee having a particular clearance, punching out the coating film by using a stamper, and stamping the punched out film onto the electrode of the substrate or the terminal of the electronic part. The transfer printing uses a special transfer printing machine. A transfer printing machine is equipped with an application mechanism for forming a solid coating film by application, a mechanism for fixing the wiring substrate and aligning the electrode of the wiring substrate, and a mechanism for three-dimensionally driving the stamper and performing punching-out and transfer pressing. The coating amount tends to vary in the transfer printing than in the screen printing and care is desirably taken for continuous operation such as cleaning and administering the stamper. Thus, the mainstream of the printing method is the screen printing method.

The dispenser discharging is a method of discharging a particular amount of conductive bonding material onto the electrode on the wiring substrate or the terminal of the electronic part and uses a dispenser. A dispenser is configured to push out a particular amount of conductive bonding material from a needle at the tip of a syringe by applying, on-demand, a pressure to the conductive bonding material in the syringe. The dispenser three-dimensionally drives the syringe, determines the position of the electrode portion on the wiring substrate, and discharges a desired amount of conductive bonding material onto the electrode. Since the conductive bonding material is discharged through a needle, the paste applied is not as thin as that formed by screen printing. However, the paste loss in the process is small and the amount of discharged paste or the position of discharge may be changed by adjusting a program. Thus, the dispenser discharging may be used in applying the conductive bonding material onto a wiring substrate and an electronic part that have steps and irregularities unsuitable for the mask plate for printing to make press-contact.

The ink jet method is a method for applying a conductive bonding material onto an electrode of a wiring substrate or a terminal of an electronic component and includes discharging a conductive bonding material from fine nozzles.

<Bonding Step>

The bonding step is a step of bonding the wiring substrate and the electronic part by heating the supplied conductive bonding material to a temperature exceeding the melting point of the second metal particle.

The bonding step is a step of applying a particular temperature while placing the electronic part or the wiring substrate onto a melt-bonded conductive bonding material supplied to the electrode of the wiring substrate or the terminal of the electronic part. Typically, a reflow device having a furnace suitable for solder heat treatment, a high-temperature vessel, or the like is used.

The mainstream of the heating method in the reflow heat treatment using the reflow device is to apply infrared rays or hot air, for example. The atmosphere in the furnace during the reflow heat treatment is either air or nitrogen. In order to suppress deterioration of the electronic part and the soldered portion due to oxidation, a reflow furnace with a nitrogen atmosphere is frequently used in recent high-density precise mounting.

The heat treatment is preferably conducted at a temperature exceeding the melting point of the second metal particle for 10 to 120 minutes. If the heat treatment is conducted at a temperature equal to or lower than the melting point of the second metal particle, the second metal particle does not turn into liquid and diffusion of the third metal particle does not proceed smoothly.

The temperature of the heat treatment depends on the melting point of the second metal particle and may be properly selected but is preferably higher than 300° C. The heat treatment may be conducted in air but is preferably conducted in a nitrogen atmosphere.

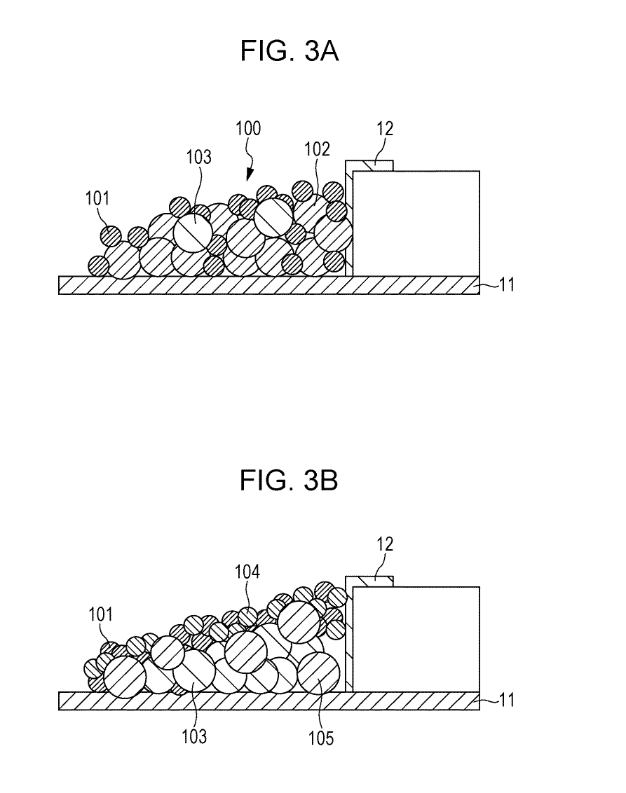

FIGS. 3A and 3B are each a schematic diagram illustrating a method of bonding a conductor by using a conductive bonding material of an embodiment.

FIG. 3A illustrates the state before heating and FIG. 3B illustrates the state after heating. Since first metal particles (Al particles) 101 have a small diameter and a small relative density, the first metal particles 101 gather in the surface of the soldered portion during heat melting and form a metal coating film having satisfactory gloss on the surface of a conductive bonding material 100. Sn in second metal particles (Sn-58 Bi alloy particles) 102 and Cu in third metal particles (Cu particles) 103 form a Cu—Sn alloy 105 due to the heating energy during melting and bismuth (Bi) 104 that has turned into a single element segregates in the surface. The third metal particles (Cu particles) 103 having a large diameter and a large relative density settle and become molten between the wiring substrate 11 and the electronic part 12 thereby establishing conduction.

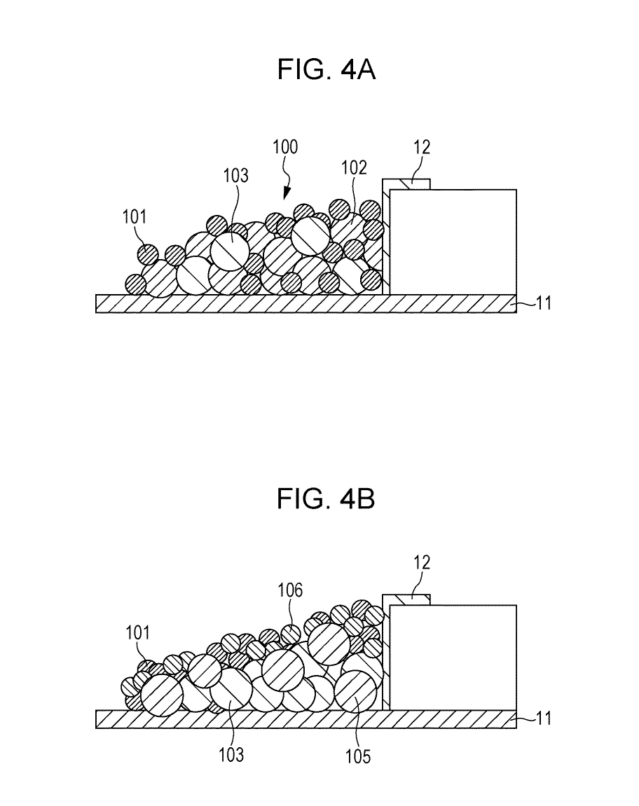

FIGS. 4A and 4B are each a schematic view illustrating a method for bonding a conductor using a conductive bonding material according to an embodiment.

FIG. 4A illustrates the state before heating and FIG. 4B illustrates the state after heating. Since the first metal particles (AgCl particles in this example) 101 have a small diameter and a small relative density, the first metal particles 101 gather in the surface of the soldered portion during heat melting and form a metal coating film having satisfactory gloss on the surface of the conductive bonding material 100. The first metal particles (AgCl particles) 101 also have an activating effect during soldering. When the oxide coating film of the conductive bonding material 100 is removed, precipitation of a metal component (Ag) 106 occurs (refer to the reaction formula below). Moreover, Sn in the second metal particles (Sn-58 Bi alloy particles) 102 and Cu in the third metal particles (Cu particles) 103 form the Cu—Sn alloy 105. The third metal particles (Cu particles) 103 having a large diameter and a large relative density settle and become molten between the wiring substrate 11 and the electronic part 12 thereby establishing conduction.

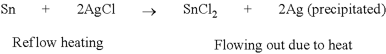

(Semiconductor Device Production Method)

A semiconductor device production method according to an embodiment includes the conductor bonding step described above and other optional steps.

The conductor bonding step may be performed in the same manner as the conductor bonding method according to an embodiment.

The optional steps may be any and may be properly selected according to the purpose. Examples of the optional steps include a step of patterning a metal wire and a step of forming an insulating film.

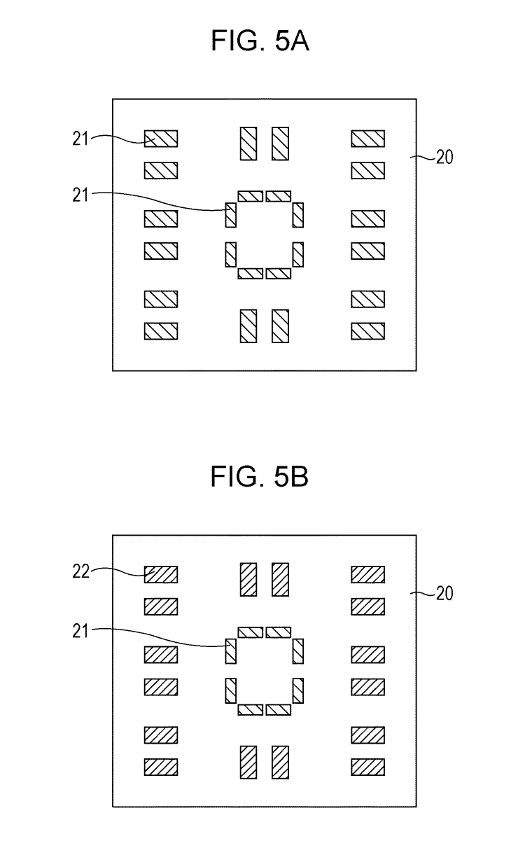

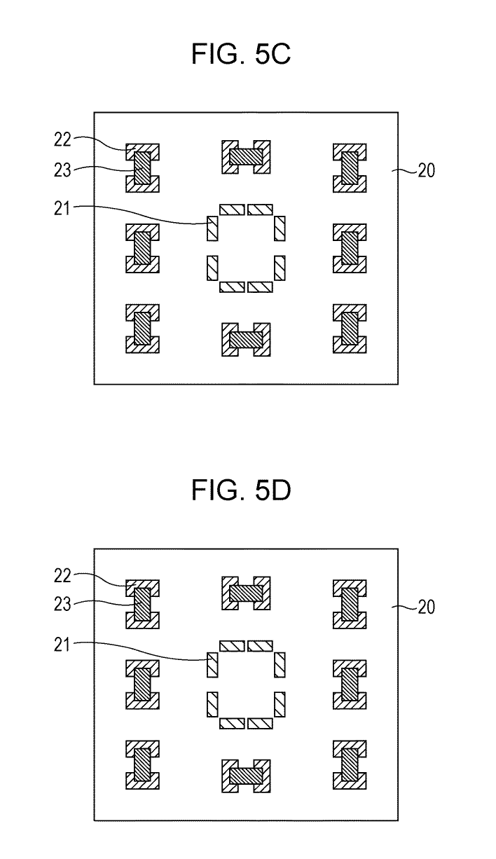

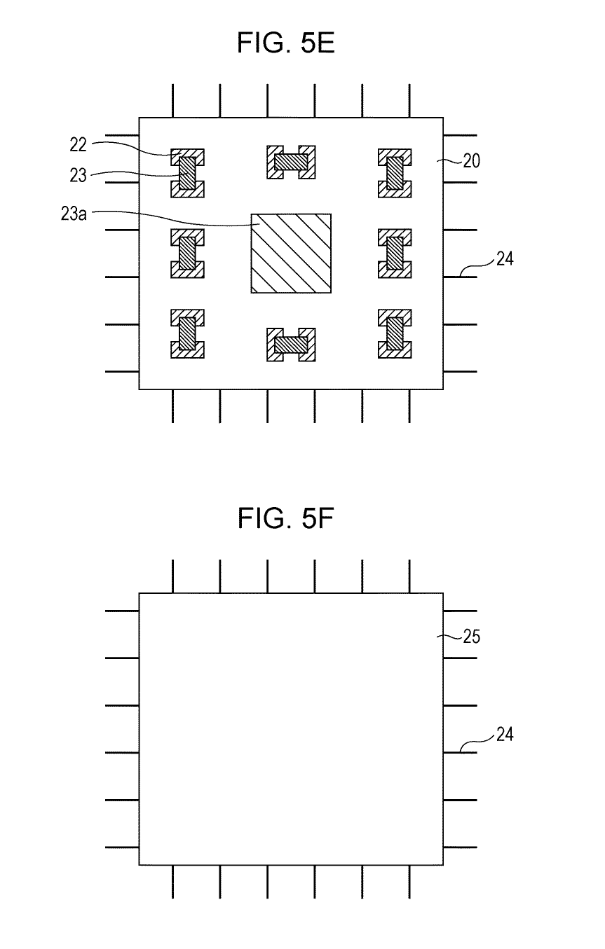

FIGS. 5A to 5G are schematic diagrams illustrating an example of steps for producing a semiconductor device according to an embodiment.

Referring to FIG. 5A, a wiring substrate 20 having electrode pads 21 is prepared.

Referring to FIG. 5B, a conductive bonding material 22 of an embodiment is applied to the wiring substrate 20 by printing and placed on some of the electrode pads 21. The printing method may be any and may be properly selected according to the purpose. An example of the printing method is a screen printing method.

Referring to FIG. 5C, electronic parts 23 are placed on the electrode pads 21.

Referring to FIG. 5D, primary reflow heating is conducted to solder the electronic parts 23.

Referring to FIG. 5E, an optional electronic part 23a is mounted, lead wires 24 are mounted, and shaping is performed when desired.

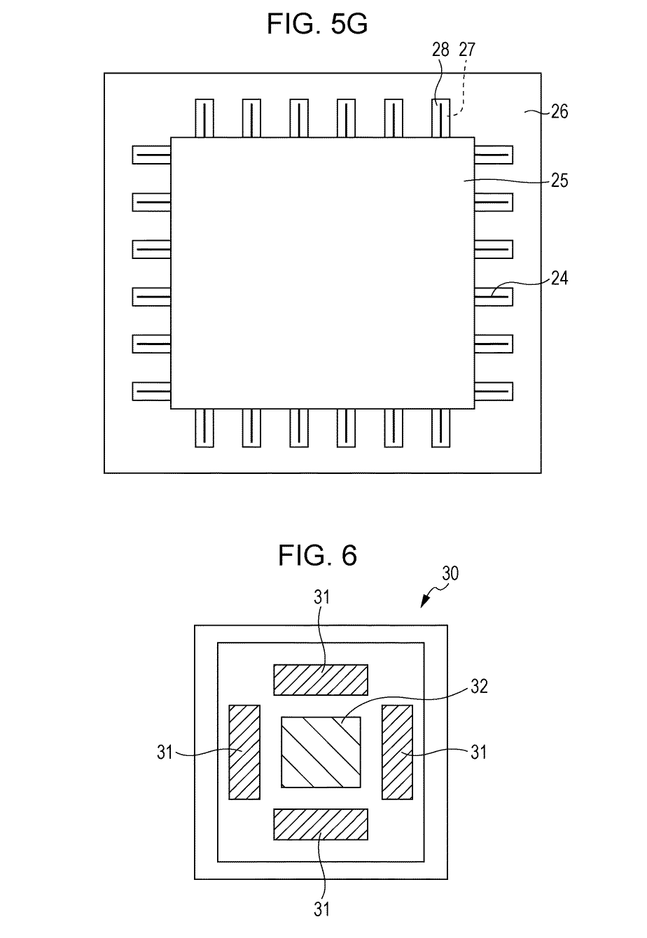

Referring to FIG. 5F, a sealing resin 25 is provided for sealing. As a result, an electronic part (0603-type chip) 30 illustrated in FIG. 6 is mounted, for example. The electronic part 30 in FIG. 6 includes surface mounted device (SMD) chips 31 and a wafer level package (WLP) 32. The sealing resin may be any resin that covers the part and may be properly selected according to the purpose. Examples of the sealing resin include thermosetting resins such as a phenol resin, a melamine resin, an epoxy resin, and a polyester resin.

Referring to FIG. 5G, a print substrate 26 having lead terminals 27 is prepared and solders 28 are placed on the lead terminals 27 by applying a solder paste on the print substrate 26 by screen-printing. Then the lead wires 24 of the electronic part are placed on the lead terminals 27 on the print substrate 26 and secondary reflow heating is conducted to solder the electronic part onto the print substrate 26. As a result, a semiconductor device is fabricated.

According to the semiconductor device production method of this embodiment, various semiconductor devices, such as flash memories, DRAMs, and FRAMs, may be produced at higher efficiency.

### EXAMPLES

The embodiments are described below more specifically by using examples which do not limit the scope of the embodiments in any way.

In Examples, the average diameter of metal particles, the relative density of the metal particles, and the melting point of the metal particles were measured as follows.

<Measurement of Average Diameter of Metal Particles>

The average diameter of metal particles was measured using a particle size distribution analyzer (laser diffraction-type particle size distribution measuring instrument, SALD-3100 produced by SHIMADZU Corporation) by dispersing metal particles in gas phase, applying a red semiconductor laser beam, comparatively analyzing a diffracted and scattered light pattern of particles input to photodetectors with a reference pattern, determining the particle diameter and the count number, and calculating the average particle diameter.

<Measurement of Relative Density of Metal Particles>

The relative density of metal particles was measured by a dimension method with a vernier caliper and a balance.

<Measurement of Melting Point of Metal Particles>

The melting point of metal particles was measured by differential scanning calorimetry (DSC) (DSC 6200 produced by Seiko Instruments Inc.) at a temperature gradient of 0.5° C./sec.

(Example 1)

Preparation of Conductive Bonding Material

(1) Metal component: 85 mass %

First metal particle (aluminum (Al) particles, average diameter: 1 μm, relative density: 2.72, melting point: 660° C.): 10 mass %

Second metal particle (Sn-58 Bi alloy particles, average diameter: 10 μm, relative density: 8.13, melting point: 139° C.): 45 mass %

Third metal particle (Cu particles, average diameter: 10 μm, relative density: 8.96, melting point: 1,084° C.): 45 mass %

(2) Flux component: 15 mass %

Rosin (MHK37-BZ produced by Matsuo Handa Co., Ltd.): 50 mass %

Organic solvent (ethylene glycol-based solvent): 50 mass %

(Example 2)

Preparation of Conductive Bonding Material A conductive bonding material of Example 2 was prepared as in Example 1 except that the first metal particle used in Example 1 was changed to the following first metal particle.

First metal particle (Sn-55 Al alloy particles, average diameter: 1 μm, relative density: 4.10, melting point: 600° C.)

(Example 3)

Preparation of Conductive Bonding Material

A conductive bonding material of Example 3 was prepared as in Example 1 except that the first metal particle used in Example 1 was changed to the following first metal particle.

First metal particle (Sn-5 In alloy particles, average diameter: 1 μm, relative density: 5.89, melting point: 200° C.)

(Example 4)

Preparation of Conductive Bonding Material

A conductive bonding material of Example 4 was prepared as in Example 1 except that the first metal particle used in Example 1 was changed to the following first metal particle.

First metal particle (Sn-5 Bi alloy particles, average diameter: 1 μm, relative density: 6.02, melting point: 200° C.)

(Example 5)

Preparation of Conductive Bonding Material

A conductive bonding material of Example 5 was prepared as in Example 1 except that the first metal particle used in Example 1 was changed to the following first metal particle.

First metal particle (SnCl₂ particles, average diameter: 1 μm, relative density: 3.95, melting point: 246° C.)

(Example 6)

Preparation of Conductive Bonding Material

A conductive bonding material of Example 6 was prepared as in Example 1 except that the first metal particle used in Example 1 was changed to the following first metal particle.

First metal particle (SnBr₂ particles, average diameter: 1 μm, relative density: 5.12, melting point: 215° C.)

(Example 7)

Preparation of Conductive Bonding Material

A conductive bonding material of Example 7 was prepared as in Example 1 except that the first metal particle used in Example 1 was changed to the following first metal particle.

First metal particle (AgCl particles, average diameter: 1 μm, relative density: 5.56, melting point: 455° C.)

(Example 8)

Preparation of Conductive Bonding Material

A conductive bonding material of Example 8 was prepared as in Example 1 except that the first metal particle used in Example 1 was changed to the following first metal particle.

First metal particle (AgBr particles, average diameter: 1 μm, relative density: 6.47, melting point: 432° C.)

(Example 9)

Preparation of Conductive Bonding Material

A conductive bonding material of Example 9 was prepared as in Example 1 except that the first metal particle used in Example 1 was changed to the following first metal particle.

First metal particle (AgI particles, average diameter: 1 μm, relative density: 5.68, melting point: 552° C.)

(Example 10)

Preparation of Conductive Bonding Material

A conductive bonding material of Example 10 was prepared as in Example 1 except that the first metal particle used in Example 1 was changed to the following first metal particle.

First metal particle (AgNO₃ particles, average diameter: 1 μm relative density: 4.35, melting point: 212° C.)

(Example 11)

Preparation of Conductive Bonding Material

A conductive bonding material of Example 11 was prepared as in Example 1 except that the first metal particle used in Example 1 was changed to the following first metal particle.

First metal particle (Sn-5 In alloy particles, average diameter: 1 μm relative density: 5.89, melting point: 200° C.): 5 mass %

First metal particle (Sn-5 Bi alloy particles, average diameter: 1 μm relative density: 6.02, melting point: 200° C.): 5 mass %

(Example 12)

Preparation of Conductive Bonding Material

A conductive bonding material of Example 12 was prepared as in Example 1 except that the second metal particle used in Example 1 was changed to the following second metal particle.

Second metal particle (Sn particles, average diameter: 10 μm, relative density: 5.82, melting point: 232° C.): 45 mass %

(Example 13)

Preparation of Conductive Bonding Material

A conductive bonding material of Example 13 was prepared as in Example 1 except that the second metal particle used in Example 1 was changed to the following second metal particle.

Second metal particle (Sn-57 Bi-1 Ag alloy particles, average diameter: 10 μm, relative density: 8.14, melting point: 139° C.): 45 mass %

(Example 14)

Preparation of Conductive Bonding Material

A conductive bonding material of Example 14 was prepared as in Example 1 except that the third metal particle used in Example 1 was changed to the following third metal particle.

Third metal particle (Ag-plated Cu particles, average diameter: 10 μm, relative density: 8.96, melting point: 1,084° C.)

(Example 15)

Preparation of Conductive Bonding Material

A conductive bonding material of Example 15 was prepared as in Example 1 except that the third metal particle used in Example 1 was changed to the following third metal particle.

Third metal particle (Sn-58 Bi alloy-plated Cu particles, average diameter: 10 μm, relative density: 8.96, melting point: 1,084° C.)

(Example 16)

Preparation of Conductive Bonding Material

A conductive bonding material of Example 16 was prepared as in Example 1 except that the third metal particle used in Example 1 was changed to the following third metal particle.

Third metal particle (Au-plated Cu particles, average diameter: 10 μm, relative density: 8.96, melting point: 1,084° C.)

(Example 17)

Preparation of Conductive Bonding Material

A conductive bonding material of Example 17 was prepared as in Example 1 except that the first metal particle used in Example 1 was changed to the following first metal particle.

First metal particle (aluminum (Al) particles, average diameter: 0.5 μm, relative density: 2.72, melting point: 660° C.)

(Example 18)

Preparation of Conductive Bonding Material

A conductive bonding material of Example 18 was prepared as in Example 1 except that the second metal particle used in Example 1 was changed to the following second metal particle.

Second metal particle (Sn-58 Bi alloy particles, average diameter: 20 μm, relative density: 8.13, melting point: 139° C.)

(Example 19)

Preparation of Conductive Bonding Material

A conductive bonding material of Example 19 was prepared as in Example 1 except that the third metal particle used in Example 1 was changed to the following third metal particle.

Third metal particle (Cu particles, average diameter: 20 μm, relative density: 8.96, melting point: 1,084° C.): 45 mass %

(Comparative Example 1)

Preparation of Conductive Bonding Material

A conductive bonding material of Comparative Example 1 was prepared as in Example 1 except that the first metal particle used in Example 1 was not contained, the second metal particle content was 50 mass %, and the third metal particle content was 50 mass %.

(Reference Example 2)

Preparation of Conductive Bonding Material

A conductive bonding material of Reference Example 2 was prepared as in Example 1 except that the second and third metal particles used in Example 1 were changed to the following second and third metal particles.

Second metal particle (Sn-95 Au alloy particles, average diameter: 10 μm, relative density: 18.65, melting point: 980° C.)

Third metal particle (Zn particles, average diameter: 10 μtm, relative density: 7.14, melting point: 419° C.)

(Reference Example 3)

Preparation of Conductive Bonding Material

A conductive bonding material of Reference Example 3 was prepared as in Example 1 except that the first metal particle used in Example 1 was changed to the following first metal particle.

First metal particle (tungsten (W) particles, average diameter: 1 μm relative density: 19.3, melting point: 3,370° C.)

(Reference Example 4)

Preparation of Conductive Bonding Material

A conductive bonding material of Reference Example 4 was prepared as in Example 1 except that the first metal particle used in Example 1 was changed to the following first metal particle.

First metal particle (aluminum (Al) particles, average diameter: 3 μm, relative density: 2.72, melting point: 660° C.)

(Reference Example 5)

Preparation of Conductive Bonding Material

A conductive bonding material of Reference Example 5 was prepared as in Example 1 except that the second metal particle used in Example 1 was changed to the following second metal particle.

Second metal particle (Sn-58 Bi alloy particles, average diameter: 7 μm, relative density: 8.13, melting point: 139° C.)

(Reference Example 6)

Preparation of Conductive Bonding Material

A conductive bonding material of Reference Example 6 was prepared as in Example 1 except that the third metal particle used in Example 1 was changed to the following third metal particle.

Third metal particle (Cu particles, average diameter: 7 μm, relative density: 8.96, melting point: 1,084° C.): 45 mass %

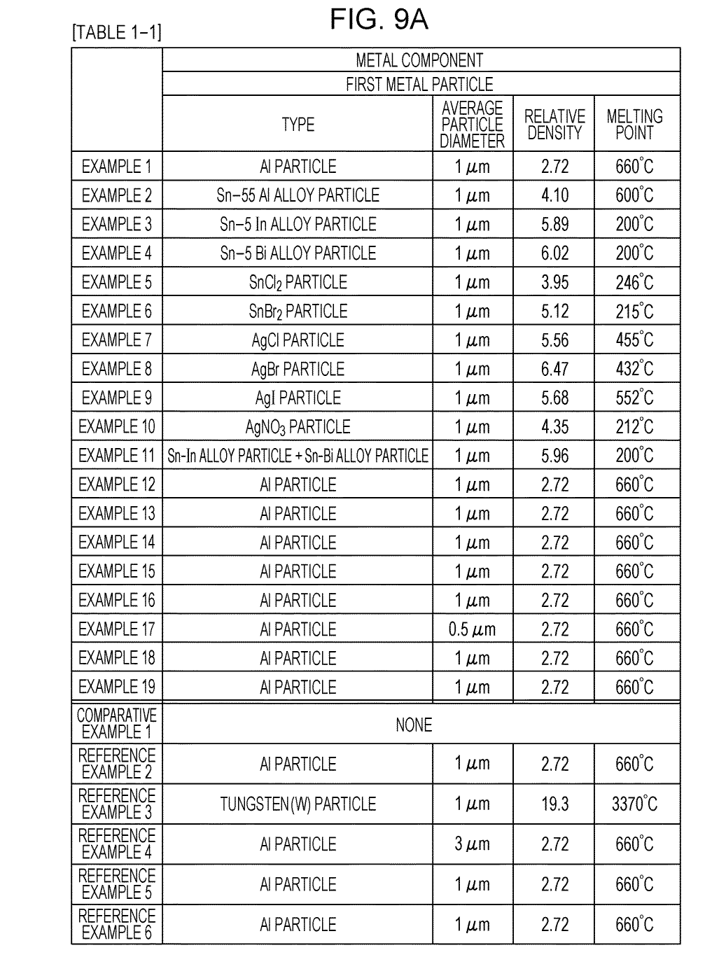

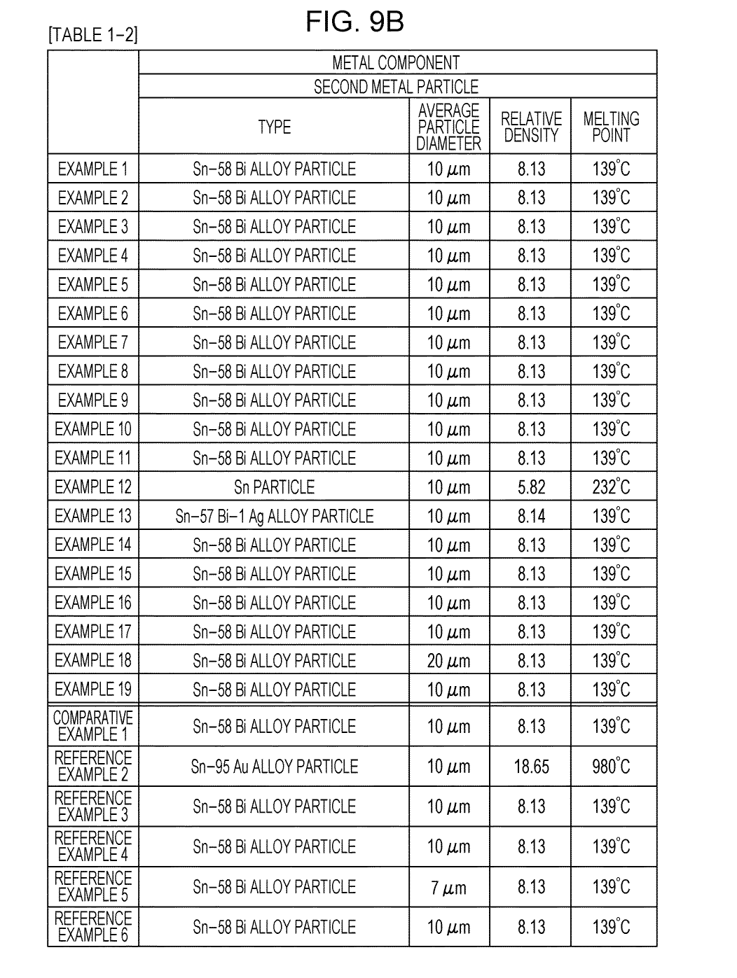

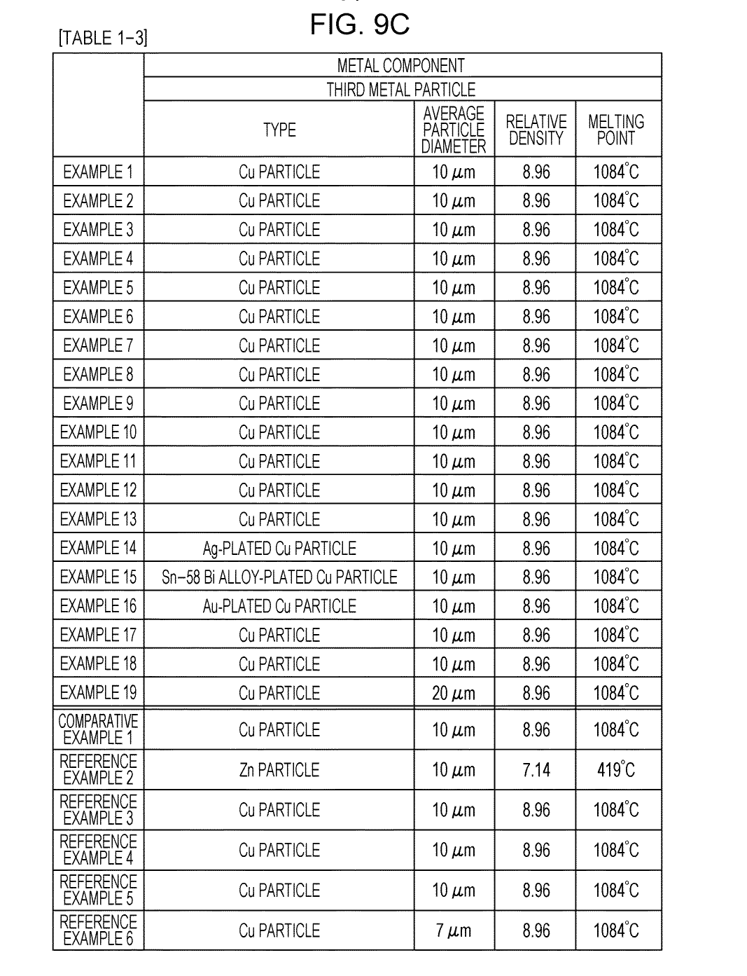

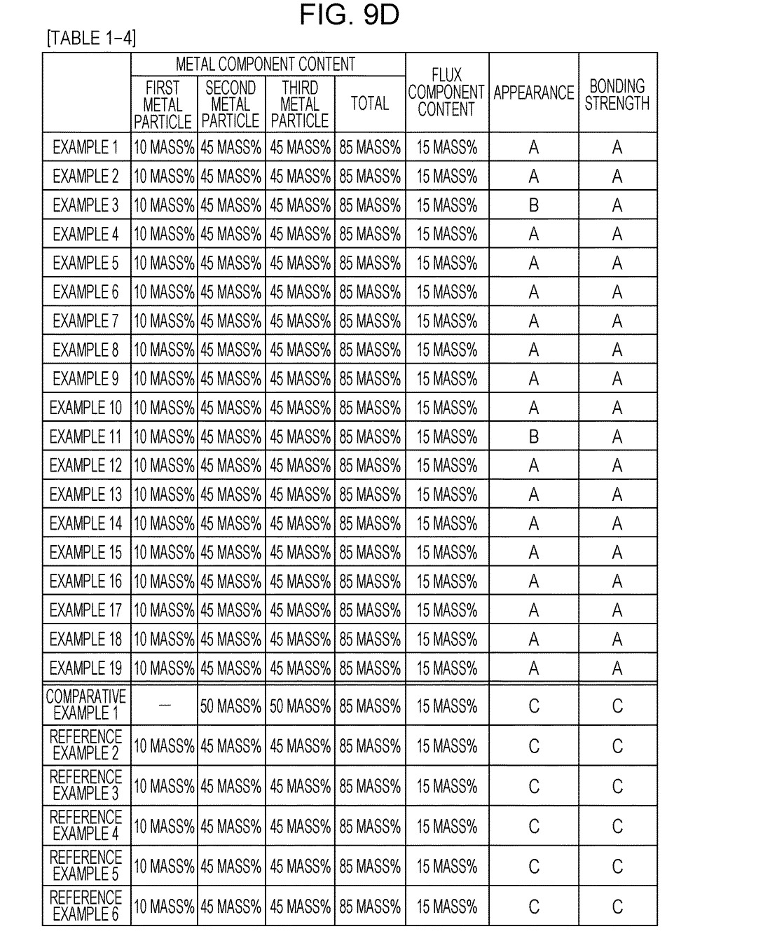

Next, the appearance and bonding strength were evaluated by using the conductive bonding materials produced. The results are presented in Tables 1-1 to 1-4 in FIGS. 9A to 9D.

<Appearance>

An electronic part was bonded to a substrate by using the conductive bonding materials under heating while retaining 180° C. for 30 minutes (in Example 12, 250° C. was retained for 30 minutes) and a surface of the resulting soldered portion was analyzed with an optical power meter (TB200 produced by Yokogawa Meters & Instruments Corporation) to determine the incoming light/reflected light output (mW) ratio. Then the samples were evaluated by the following standard.

[Evaluation Standard]

A: The incoming light/reflected light output (mW) ratio was 70% or higher.

B: The incoming light/reflected light output (mW) ratio was 50% or higher but less than 70%.

C: The incoming light/reflected light output (mW) ratio was less than 50%.

<Bonding Strength>

An electronic part was bonded to a substrate by using the conductive bonding materials under heating while retaining 180° C. for 30 minutes (in Example 12, 250° C. was retained for 30 minutes) and the resulting soldered portion was analyzed with a shear strength tester (SERIES 4000 produced by Dage Japan Co., Ltd.) to determine the bonding strength ratio of the conductive bonding material relative to a Sn—Ag—Cu alloy solder. The samples were evaluated by the following standard.

[Evaluation Standard]

A: The bonding strength ratio relative to the Sn—Ag—Cu alloy solder was 70% or higher (700 gf/pin or higher).

B: The bonding strength ratio relative to the Sn-Ag-Cu alloy solder was 60% or higher (600 gf/pin or higher) but less than 70% (less than 700 gf/pin).

C: The bonding strength ratio relative to the Sn-Ag-Cu alloy solder was less than 60% (less than 600 gf/pin).

FIGS. 9A to 9D present Tables 1-1 to 1-4 indicating compositions of conductive bonding materials of Examples, Reference Example, and Comparative Examples and results of evaluating appearance and bonding strength.

(Example 20)

Bonding of Electronic Part

An electronic part was bonded to a wiring substrate as follows by using the conductive bonding material of Example 4.

The conductive bonding material of Example 4 was applied (supplied) to a wiring substrate (substrate base) having a Cu electrode L: 200 μm×W: 100 μm in size by screen-printing, an electronic part (0603-type chip) was placed thereon, and bonding of the electronic part to the wiring substrate was performed by retaining 180° C. for 30 minutes.

As illustrated in FIGS. 3A and 3B, the first metal particles (Al particles) 101 having a small diameter and a small relative density gathered in the surface of the soldered portion during heat melting and formed a metal coating film with satisfactory gloss on the surface of the conductive bonding material 100. Sn in the second metal particles (Sn-58 Bi alloy particles) 102 and Cu in the third metal particles (Cu particles) 103 formed a Cu—Sn alloy 105 due to the heating energy during melting and bismuth (Bi) 104 that had turned into a single element segregated in the surface. The third metal particles (Cu particles) 103 having a large diameter and a large relative density settled and became molten between the wiring substrate 11 and the electronic part 12, thereby establishing conduction.

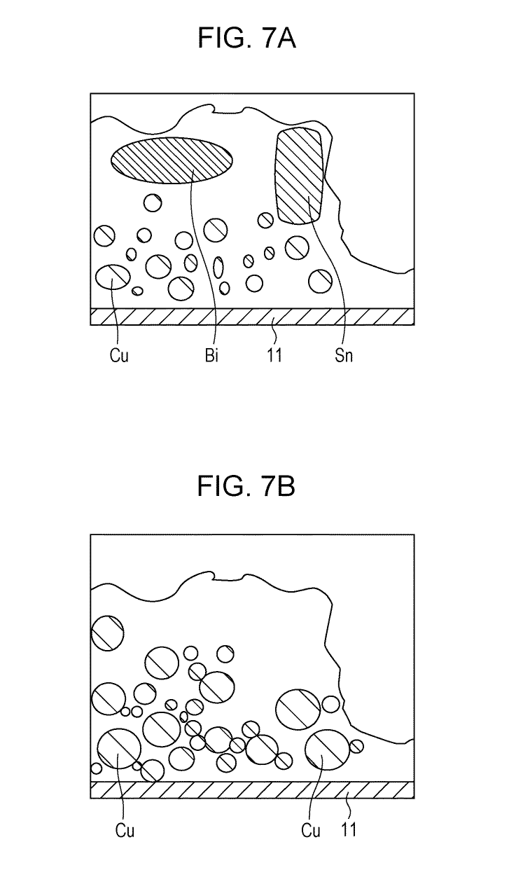

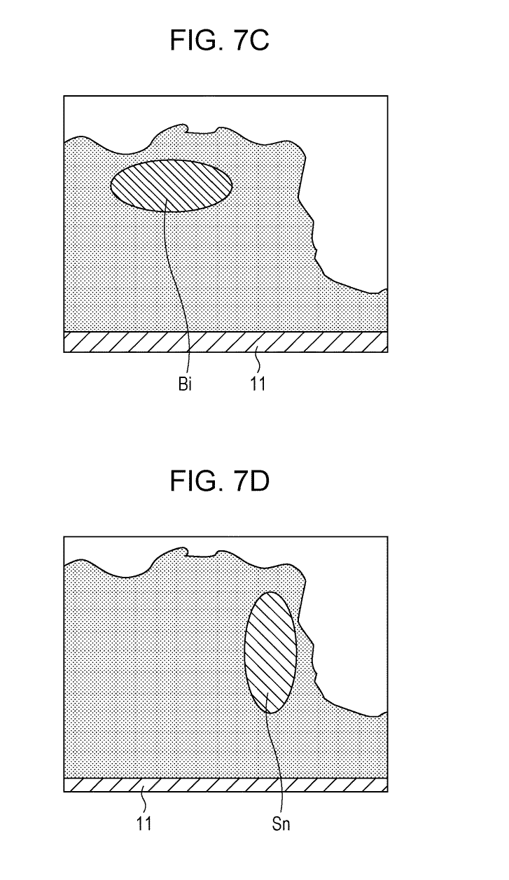

FIGS. 7A to 7D present results of measuring the dispersed states of the Cu particles, Sn particles, and Bi particles after bonding the electronic part to the wiring substrate with the conductive bonding material of Example 4. The measurement was conducted by energy dispersive X-ray spectrometry. Energy dispersive X-ray spectrometry is an analytical technique involving detecting characteristic X rays generated during scanning of an object with an electron beam or the like and investigating the substances that constitute the object from the energy distribution obtained from the X-rays. Identity of the elements (metals) and distribution of the elements (metals) may be measured by this technique.

FIG. 7A is a schematic diagram of a mapping image photograph of Cu, Bi, and Sn measured with an energy dispersive X-ray microanalyzer:EDS after an electronic part was bonded to a wiring substrate with the conductive bonding material of Example 4.

FIG. 7B is a schematic diagram of a mapping image photograph of Cu measured with energy dispersive X-ray microanalyzer:EDS after an electronic part was bonded to a wiring substrate with the conductive bonding material of Example 4.

FIG. 7C is a schematic diagram of a mapping image photograph of Bi measured with energy dispersive X-ray microanalyzer:EDS after an electronic part was bonded to a wiring substrate with the conductive bonding material of Example 4.

FIG. 7D is a schematic diagram of a mapping image photograph of Sn measured with energy dispersive X-ray microanalyzer:EDS after an electronic part was bonded to a wiring substrate with the conductive bonding material of Example 4.

The results presented in FIGS. 7A to 7D confirm that the state after heating illustrated in FIG. 3B is achieved when an electronic part is bonded to a wiring substrate with the conductive bonding material of Example 4 in Example 20.

The resulting bonded electronic part had a soldered portion having gloss and could be inspected with an automatic appearance inspection system using a laser beam.

(Example 21)

Bonding of Electronic Part

An electronic part was bonded to a wiring substrate as follows by using the conductive bonding material of Example 7.

The conductive bonding material of Example 7 was applied (supplied) to a wiring substrate (substrate base) having a Cu electrode L: 200 μm×W: 100 μm in size by screen-printing, an electronic part (0603-type chip) was placed thereon, and bonding of the electronic part to the wiring substrate was performed by retaining 180° C. for 30 minutes.

As illustrated in FIGS. 4A and 4B, the first metal particles (AgCl particles) 101 having a small diameter and a small relative density gathered in the surface of the soldered portion during heat melting and formed a metal coating film with satisfactory gloss on the surface of the conductive bonding material 100. The first metal particles (AgCl particles) 101 also have an activating effect during soldering. When the oxide coating film of the conductive bonding material 100 was removed, precipitation of the metal component (Ag) 106 occurred (refer to the reaction formula below). Moreover, Sn in the second metal particles (Sn-58 Bi alloy particles) 102 and Cu in the third metal particles (Cu particles) 103 formed the Cu—Sn alloy 105 due to the heat energy during melting. The third metal particles (Cu particles) 103 having a large diameter and a large relative density settled and became molten between the wiring substrate 11 and the electronic part 12 thereby establishing conduction.

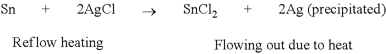

The resulting bonded electronic part had a soldered portion having gloss and could be inspected with an automatic appearance inspection system using a laser beam.

(Example 22)

Preparation of Conductive Bonding Material

(1) Metal component: 85 mass %
First metal particle (aluminum (Al) particles, average diameter: 1 μm relative density: 2.72, melting point: 660° C.): Z mass %
Second metal particle (Sn particles, average diameter: 10 μm, relative density: 5.82, melting point: 232° C.): Y mass %
Third metal particle (Cu particles, average diameter: 10 μm, relative density: 8.96, melting point: 1,084° C.): X mass %

(2) Flux component: 15 mass %
Rosin (MHK37-BZ produced by Matsuo Handa Co., Ltd.): 50 mass %
Organic solvent (ethylene glycol-based solvent): 50 mass %

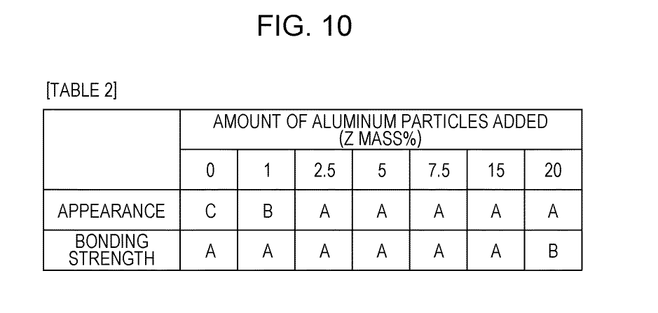

Based on the composition above, the aluminum particle (first metal particle) content (Z mass %) was changed to 0 mass %, 1 mass %, 2.5 mass %, 5 mass %, 7.5 mass %, 15 mass %, and 20 mass % and conductive bonding materials indicated in Table 2 in FIG. 10 were prepared while adjusting the ratio of the amount of the second metal particle added (Y mass %) to the amount of the third metal particle added (X mass %) to 5:5 (mass ratio).

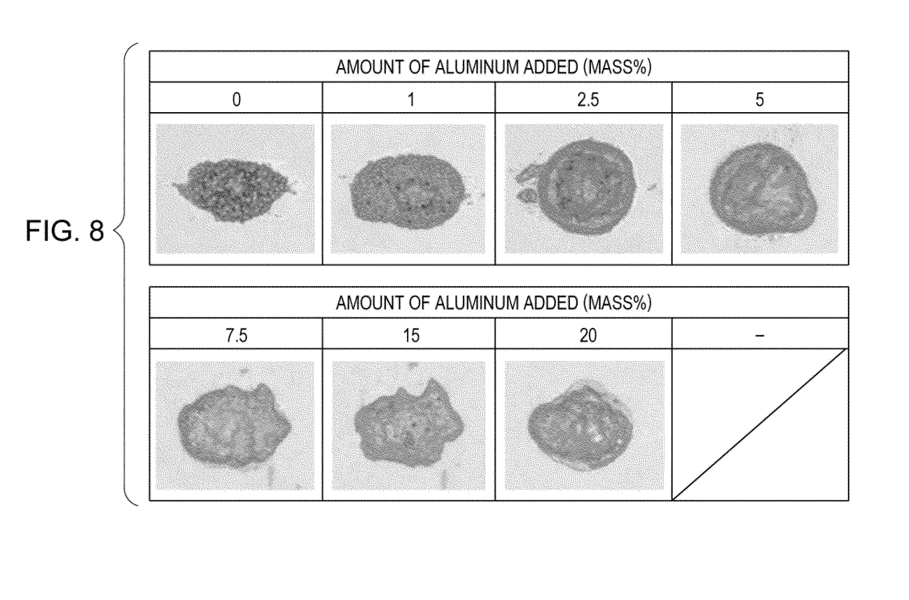

Then as in Examples 1 to 19, the appearance and bonding strength were evaluated. The results are presented in Table 2 in FIG. 10. Photographs of surface states of the conductive bonding materials prepared are presented in FIG. 8.

The results in Table 2 in FIG. 10 and FIG. 8 confirm that the aluminum particles (first metal particle) having a small relative density gather in the surface of the conductive bonding material during heat melting and may form a metal coating film having a satisfactory gloss on the surface of the conductive bonding material and that the aluminum particle content is preferably in the range of 1.5 mass % to 20 mass % and more preferably in the range of 2.5 mass % to 15 mass % from the viewpoints of appearance and bonding strength.

The same results were obtained when Sn—Al alloy particles, Sn—Bi alloy particles, AgNO₃ particles, AgCl particles, AgBr particles, and SnCl particles were used as the first metal particle instead of aluminum (Al) particles.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A conductive bonding material comprising:
a first metal particle;
a second metal particle having an average particle diameter larger than an average particle diameter of the first metal particle; and
a third metal particle having an average particle diameter larger than the average particle diameter of the first metal particle, a relative density larger than a relative density of the first metal particle, and a melting point higher than a melting point of the second metal particle.

2. The conductive bonding material according to claim 1, wherein the average particle diameter of the first metal particle is 1 μm or less, and the average particle diameters of the second and third metal particles are each 10 μm or more.

3. The conductive bonding material according to claim 1, wherein the first metal particle is an aluminum particle.

4. The conductive bonding material according to claim 1, wherein the first metal particle is a particle made of Sn—Al alloys, Sn—In alloys, or Sn—Bi alloys.

5. The conductive bonding material according to claim 1, wherein the first metal particle is a particle made of SnCl₂, SnBr, AgCl, AgBr, AgI, AgNO₃, and AlCl₃.

6. The conductive bonding material according to claim 1, wherein a melting point of the first metal particle is lower than the melting point of the third metal particle.

7. The conductive bonding material according to claim 1, wherein the relative density of the first metal particle is 2.0 or more and 6.0 or less and the relative density of the third metal particle is 8.0 or more.

8. The conductive bonding material according to claim 1, wherein the melting point of the second metal particle is 300° C. or less and the melting point of the third metal particle is 900° C. or more.

9. The conductive bonding material according to claim 1, wherein the second metal particle is at least one particle selected from the group consisting of a tin particle, a tin-bismuth alloy particle, a tin-bismuth-silver alloy particle, and a tin-indium alloy particle.

10. The conductive bonding material according to claim 1, wherein the third metal particle is at least one particle selected from the group consisting of a gold particle, a silver particle, a copper particle, a gold-plated copper particle, a tin-bismuth alloy-plated copper particle, and a silver-plated copper particle.

11. The conductive bonding material according to claim 1, wherein a first metal particle content is 1.5 to 20 mass % relative to all metal components.

12. The conductive bonding material according to claim 1, wherein a metal content is 50 to 95 mass % relative to the conductive bonding material.

13. The conductive bonding material according to claim 1, wherein conductive bonding material includes a epoxy-based flux material or a rosin-based flux material.

14. The conductive bonding material according to claim 1, wherein a flux material is 5 to 50 mass % relative to the conductive bonding material.

15. A conductor bonding method comprising:
supplying a conductive bonding material to an electrode of a wiring substrate, a terminal of an electronic part to be mounted to the electrode, or both the electrode and the terminal, the conductive bonding material containing a first metal particle, a second metal particle having an average particle diameter larger than an average particle diameter of the first metal particle, and a third metal particle having an average particle diameter larger than the average particle diameter of the first metal particle, a relative density larger than a relative density of the first metal particle, and a melting point higher than a melting point of the second metal particle; and
bonding the wiring substrate and the electronic part to each other by heating the supplied conductive bonding material at a temperature exceeding the melting point of the second metal particle.

16. A semiconductor device production method comprising:
bonding a conductor, including
supplying a conductive bonding material to an electrode of a wiring substrate, a terminal of an electronic part to be mounted to the electrode, or both the electrode and the terminal, the conductive bonding material containing a first metal particle, a second metal particle having an average particle diameter larger than an average particle diameter of the first metal particle, and a third metal particle having an average particle diameter larger than the average particle diameter of the first metal particle, a relative density larger than a relative density of the first metal particle, and a melting point higher than a melting point of the second metal particle, and
bonding the wiring substrate and the electronic part to each other by heating the supplied conductive bonding material at a temperature exceeding the melting point of the second metal particle.
